(19) United States
(12) Patent Application Publication
(10) Pub. No.: US 2024/0154328 A1
(43) Pub. Date: May 9, 2024

(54) BOARD CONNECTOR AND ELECTRICAL DEVICE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventor: Hiroki KOBAYASHI, Mie (JP)

(21) Appl. No.: 18/280,225

(22) PCT Filed: Feb. 16, 2022
(86) PCT No.: PCT/JP2022/006113

§ 371 Date: Sep. 3, 2023

(30) Foreign Application Priority Data
Mar. 4, 2021 (JP) 2021-034114

(51) Int. Cl. H01R 12/71

(52) U.S. Cl. CPC H01R 12/716

(57) ABSTRACT

A housing includes a terminal fixing wall, through which the terminal is passed to be fixed, a bottom wall to be placed on the circuit board and an upper wall facing the bottom wall. The terminal includes a terminal connecting portion located inside the housing with the terminal fixed to the terminal fixing wall, an extending portion disposed from the terminal fixing wall to outside of the housing and extending toward the bottom wall along the terminal fixing wall and a board connecting portion extending in a region between the bottom wall of the housing and the circuit board on a tip of the extending portion and to be soldered to the conductive path of the circuit board. The upper wall includes an upper opening open in at least a part of a region corresponding to the board connecting portion in a direction intersecting the bottom wall.

### TECHNICAL FIELD

The present disclosure relates to a board connector and an electrical device.

### BACKGROUND

Conventionally, a board connector described in Patent Document 1 is known. This board connector includes a housing and a contact element mounted in the housing. The contact element includes a contact leg piece to be electrically connected to a mating connector, a first soldered connection leg piece connected to the contact leg piece and extending along the rear surface of the housing, and a second soldered connection leg piece extending perpendicularly to the first soldered connection leg piece and along the bottom surface of the housing in parallel to the contact leg piece.

### PRIOR ART DOCUMENT

### Patent Document

Patent Document 1: JP 2005-243633 A

### SUMMARY OF THE INVENTION

### Problems to be Solved

However, according to the above technique, since a part where the first soldered connection leg piece and a circuit board are soldered is located on a lower end part of the first soldered connection leg piece, it has been difficult to inspect the soldered part. Further, a part where the second soldered connection leg piece and the circuit board are soldered is located between the bottom wall of the housing and the circuit board. Thus, there has been a problem that the soldered part cannot be easily inspected.

The present disclosure was completed on the basis of the above situation and aims to provide a technique capable of easily inspecting a soldered part of a board connector and a circuit board.

### Means to Solve the Problem

The present disclosure is directed to a board connector to be mounted on a circuit board including a conductive path, the board connector being provided with a housing and a terminal to be fixed to the housing, the housing including a terminal fixing wall, the terminal being passed through and fixed to the terminal fixing wall, a bottom wall to be placed on the circuit board and an upper wall facing the bottom wall, the terminal including a terminal connecting portion located inside the housing with the terminal fixed to the terminal fixing wall, an extending portion disposed from the terminal fixing wall to outside of the housing and extending toward the bottom wall along the terminal fixing wall and a board connecting portion extending in a region between the bottom wall of the housing and the circuit board on a tip of the extending portion and to be soldered to the conductive path of the circuit board, the upper wall including an upper opening open in at least a part of a region corresponding to the board connecting portion in a direction intersecting the bottom wall, and the terminal connecting portion and the board connecting portion being formed at positions shifted in the direction intersecting the bottom wall.

### Effect of the Invention

According to the present disclosure, a soldered part of a board connector and a circuit board can be easily inspected.

### BRIEF DESCRIPTION OF THE DRAWINGS

FIG. 1 is a section showing an electrical device according to one embodiment.

FIG. 2 is a plan view showing a configuration in which a board connector is mounted on a circuit board.

FIG. 3 is a perspective view showing the board connector.

FIG. 4 is a perspective view showing the board connector viewed from a different angle from FIG. 3.

FIG. 5 is a plan view showing the board connector.

FIG. 6 is a perspective view showing a terminal.

FIG. 7 is a plan view showing the terminal.

FIG. 8 is a section along VIII-VIII in FIG. 9.

FIG. 9 is a back view showing the board connector.

FIG. 10 is a section along X-X in FIG. 9.

### DETAILED DESCRIPTION TO EXECUTE THE INVENTION

[Description of Embodiments of Present Disclosure]

First, embodiments of the present disclosure are listed and described.

(1) The present disclosure is directed to a board connector to be mounted on a circuit board including a conductive path, the board connector being provided with a housing and a terminal to be fixed to the housing, the housing including a terminal fixing wall, the terminal being passed through and fixed to the terminal fixing wall, a bottom wall to be placed on the circuit board and an upper wall facing the bottom wall, the terminal including a terminal connecting portion located inside the housing with the terminal fixed to the terminal fixing wall, an extending portion disposed from the terminal fixing wall to outside of the housing and extending toward the bottom wall along the terminal fixing wall and a board connecting portion extending in a region between the bottom wall of the housing and the circuit board on a tip of the extending portion and to be soldered to the conductive path of the circuit board, the upper wall including an upper opening open in at least a part of a region corresponding to the board connecting portion in a direction intersecting the bottom wall, and the terminal connecting portion and the board connecting portion being formed at positions shifted in the direction intersecting the bottom wall.

A part where the board connecting portion and the circuit board are soldered can be easily inspected by viewing or inspection with a camera or the like through the upper opening.

(2) Preferably, a first bent portion bent in a direction intersecting an extending direction of the terminal connecting portion on an end part of the terminal connecting portion and a second bent portion bent and connected to the extending portion on an end part of the first bent portion are provided between the terminal connecting portion and the extending portion, and a part of the first bent portion opposite to the terminal connecting portion serves as a pressed portion, a jig for press-fitting the terminal into the housing being brought into contact with the pressed portion.

In a part of the first bent portion opposite to the terminal connecting portion, a region corresponding to at least a cross-sectional area of the terminal connecting portion can be pressed by the jig. In this way, a step of press-fitting the terminal into the housing can be reliably performed.

(3) Preferably, a part of the second bent portion opposite to the extending portion serves as a front stop portion for suppressing the terminal from being excessively press-fit into the housing.

By the contact of the front stop portion with the terminal fixing wall, the terminal is suppressed from being excessively press-fit.

(4) Preferably, the bottom wall of the housing includes a lower opening open in a region corresponding to the board connecting portion.

With the housing mounted on the circuit board, a height of the housing in a direction intersecting a plate surface of the circuit board can be reduced as compared to the case where the bottom wall does not include the lower opening. In this way, the board connector can be reduced in height in a state mounted on the circuit board.

(5) The present disclosure is directed to an electrical device with the board connector of any one of (1) to (4) described above, a circuit board mounted with the board connector, and a case for accommodating the circuit board mounted with the board connector, the case including a cover portion at a position corresponding to the upper opening of the board connector, the cover portion projecting toward the housing and covering the upper opening.

By covering the upper opening with the cover portion, the entrance of external matters such as dust into the housing can be suppressed. In this way, the electrical connection reliability of the board connector can be improved.

[Details of Embodiment of Present Disclosure]

An embodiment of the present disclosure is described below. The present disclosure is not limited to these illustrations, but is represented by claims and intended to include all changes in the scope of claims and in the meaning and scope of equivalents.

### Embodiment

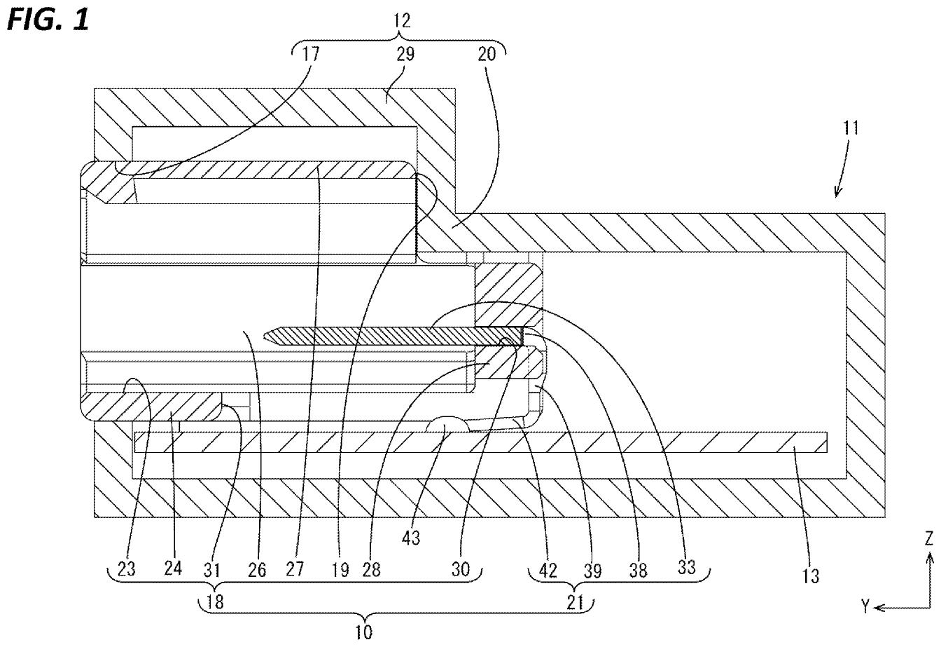

An embodiment in which the present disclosure is applied to an electrical device 11 including a board connector 10 is described with reference to FIGS. 1 to 10. The electrical device 11 of this embodiment includes a case 12, a circuit board 13 accommodated in the case 12 and the board connector 10 mounted on the circuit board 13. In the following description, a direction indicated by an arrow Z is referred to as an upward direction, a direction indicated by an arrow Y is referred to as a forward direction and a direction indicated by an arrow X is referred to as a leftward direction. Further, for a plurality of identical members, only some members may be denoted by a reference sign and the other members may not be denoted by the reference sign.

[Electrical Device 11]

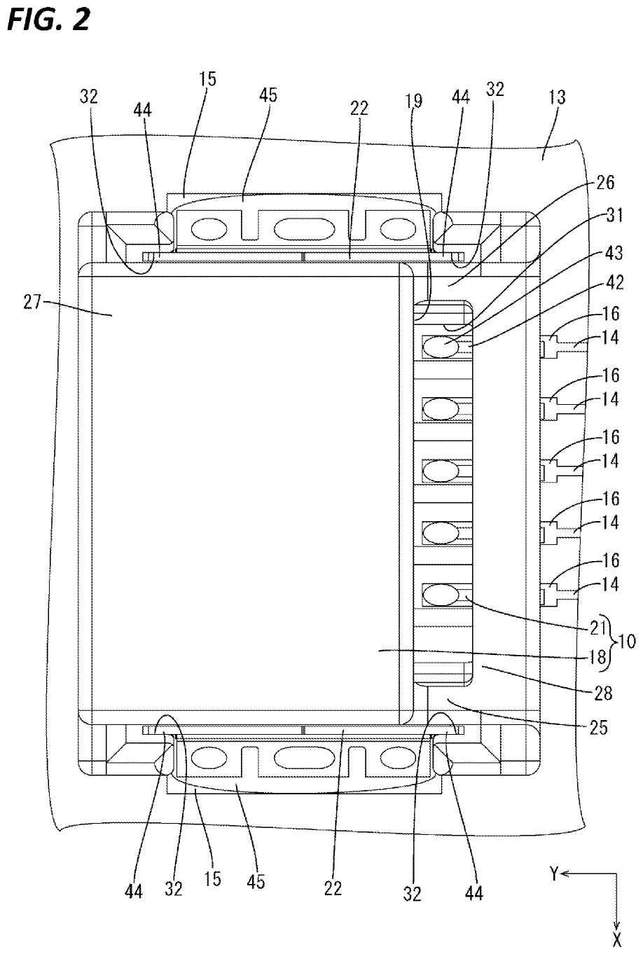

As shown in FIG. 1, the electrical device 11 includes the case 12 made of synthetic resin. The circuit board 13 is accommodated in the case 12. The electrical device 11 according to the embodiment is not particularly limited and can be, for example, an electrical connection box for turning on or off a power supply of an unillustrated vehicle, a DC/DC converter or the like. Although not shown in detail, the circuit board 13 is fixed to the case 12 by a known method, such as using screws. As shown in FIG. 2, the circuit board 13 includes conductive paths 14 and fixing lands 15 formed on an insulating board by a known printed wiring technique. The conductive paths 14 and the fixing lands 15 are formed of electrically conductive metal such as by copper foils. The conductive paths 14 include terminal lands 16 to be described later. The conductive paths 14 and the fixing lands 15 may or may not be electrically connected.

As shown in FIG. 1, a connector opening 17 open forward is formed in the front wall of the case 12. A housing 18 of the board connector 10 is accommodated into the connector opening 17. A bulging portion 29 bulging upward is formed at a position behind the connector opening 17 on the upper wall of the case 12. A rear end part of the bulging portion 29 serves as a cover portion 20 for closing an upper opening 19 from above by entering the upper opening 19 of the housing 18 to be described later.

[Board Connector 10]

As shown in FIG. 2, in the board connector 10, a plurality of (five in this embodiment) terminals 21 are mounted in the housing 18, this housing 18 is placed on the circuit board 13, each terminal 21 is connected to the circuit board 13 by reflow soldering, fixing members 22 made of metal are mounted on both side surfaces of the housing 18, and these fixing members 22 are likewise fixed on the circuit board 13 by reflow soldering.

[Housing 18]

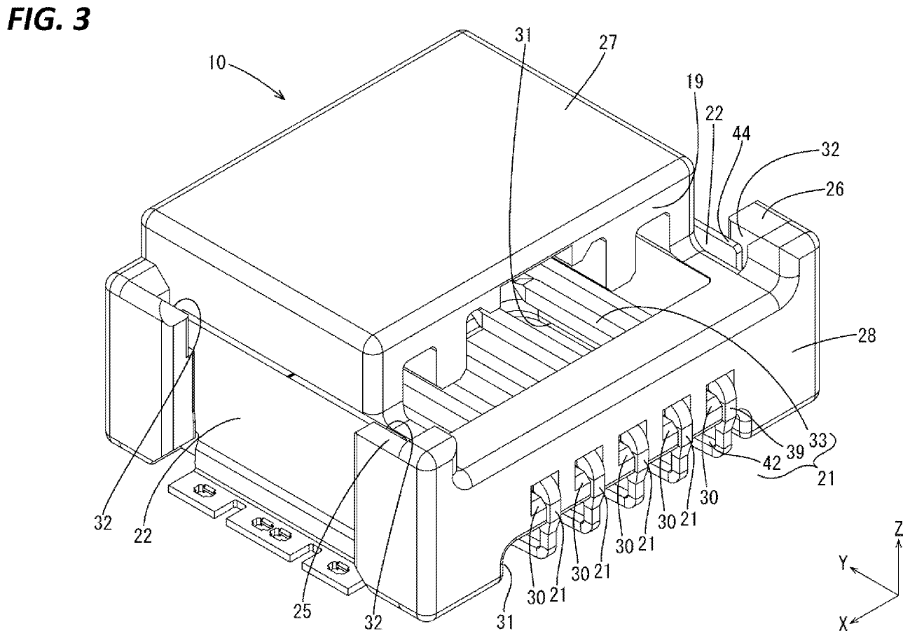

The housing 18 is made of synthetic resin and, as shown in FIG. 3, in the form of a block elongated in a lateral direction as a whole. As shown in FIG. 1, an opening 23 into which a mating female housing (not shown) is fit, is formed to be open forward in the front surface of the housing 18.

As shown in FIG. 1, the housing 18 includes a bottom wall 24 to be placed on the upper surface of the circuit board 13, a left side wall 25 extending upward from the left edge of the bottom wall 24, a right side wall 26 extending upward from the right edge of the bottom wall 24, an upper wall 27 coupling the upper ends of the left and right side walls 25, 26, and a terminal fixing wall 28 formed on a side opposite to an opening side of the opening 23 and having the plurality of terminals 21 fixed thereto. The upper wall 27 is facing the bottom wall 24.

As shown in FIG. 3, a plurality of (five in this embodiment) through holes 30 penetrating through the terminal fixing wall 28 in a front-rear direction are formed side by side in the lateral direction in the terminal fixing wall 28. The terminals 21 are fixed to the terminal fixing wall 28 while being passed in the front-rear direction in the through holes 30.

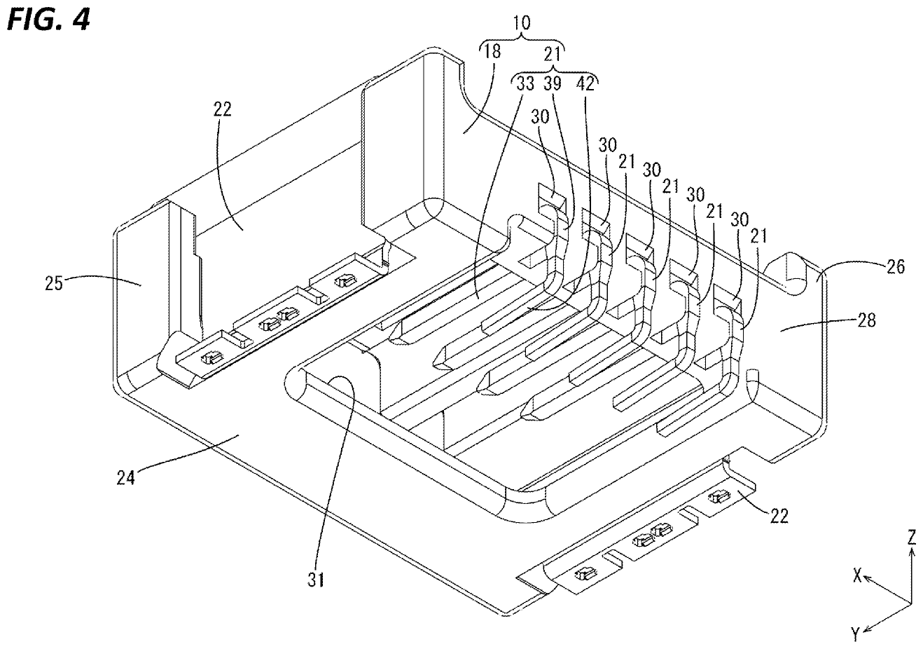

As shown in FIG. 4, the bottom wall 24 includes a lower opening 31 open downward and extending over substantially two-thirds length from a rear end part in the front-rear direction. The lower opening 31 has a substantially rectangular opening edge when viewed from below. By forming the lower opening 31, the bottom wall 24 is substantially C-shaped when viewed from below. A part corresponding to the lower opening 31, out of a lower end part of the terminal fixing wall 28, is recessed somewhat upward.

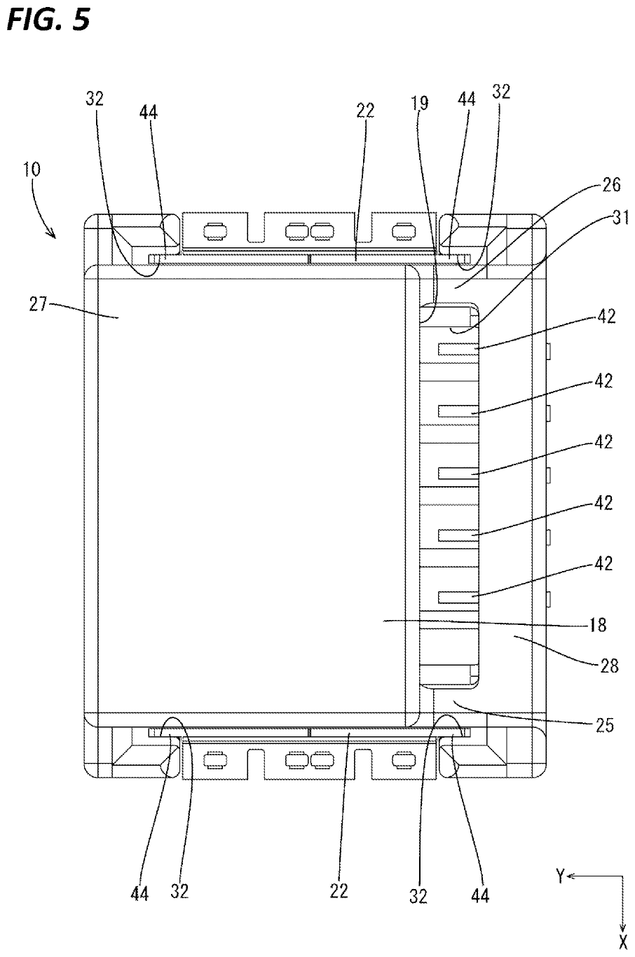

As shown in FIG. 5, the upper wall 27 includes an upper opening 19 open upward and extending over substantially one-third length from a rear end part in the front-rear direction. The rear end part of the upper wall 27 is cut out by the upper opening 19. When the housing 18 is viewed from above, the upper surface of the circuit board 13 can be viewed through the upper and lower openings 19, 31 (see FIG. 2). A part corresponding to the upper opening 19, out of an upper end part of the terminal fixing wall 28, is recessed somewhat downward (see FIG. 3).

As shown in FIG. 5, locking grooves 32 for fixing the fixing members 22 are formed to extend in a vertical direction at positions near both front and rear ends on the left side surface of the left side wall 25 of the housing 18. A width of the locking groove 32 is so set that a metal plate material constituting the fixing member 22 is insertable.

As shown in FIG. 5, locking grooves 32 for fixing the fixing members 22 are formed to extend in the vertical direction at positions near both front and rear ends on the right side surface of the right side wall 26 of the housing 18. A width of the locking groove 32 is so set that the metal plate material constituting the fixing member 22 is insertable.

[Terminals 21]

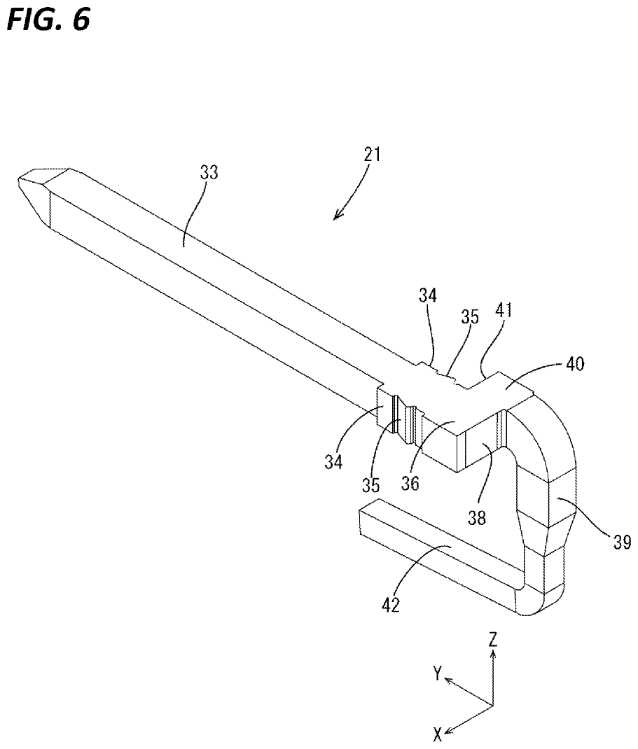

As shown in FIG. 6, the terminal 21 is formed by bending an elongated metal plate material into a predetermined shape. A front end part of the terminal 21 serves as a terminal connecting portion 33 to be connected to a female terminal (not shown) mounted in the mating housing. The terminal connecting portion 33 is formed to extend in the front-rear direction (an example of an extending direction of the terminal connecting portion 33).

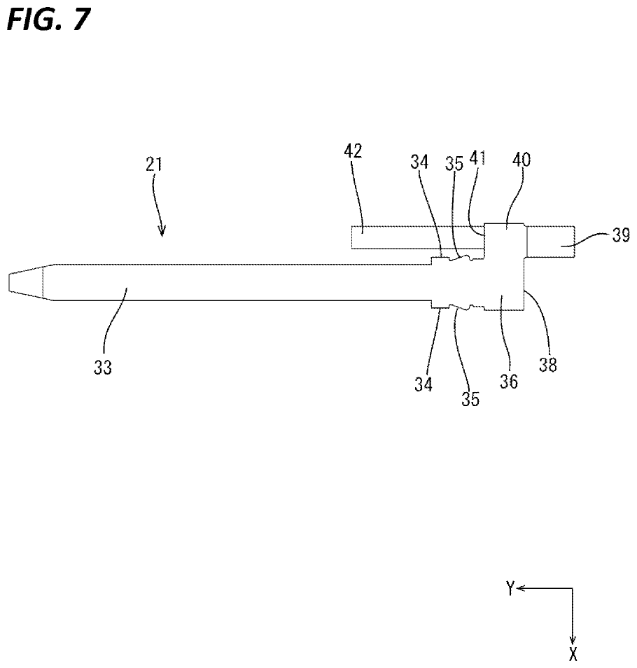

As shown in FIG. 7, front projections 34 projecting in the lateral direction and rear projections 35 provided behind the front projection 34 and projecting in the lateral direction are formed at positions near a rear end part of the terminal connecting portion 33. The front projection 34 has a rectangular shape when viewed from above. The rear projection 35 has a triangular shape when viewed from above.

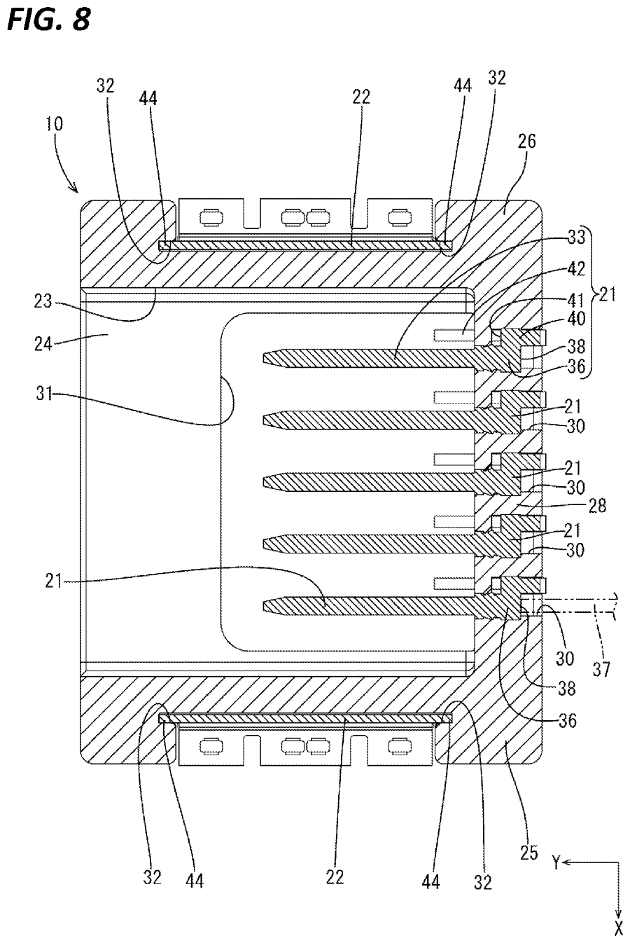

As shown in FIG. 8, the terminal 21 is fixed in the housing 18 by press-fitting the front and rear projections 34, 35 into the inner wall of the through hole 30. With the terminal 21 fixed in the housing 18, the terminal connecting portion 33 is located in the opening 23 of the housing 18.

As shown in FIG. 7, the rear end part of the terminal connecting portion 33 serves as a first bent portion 36 bent rightward (an example of a direction intersecting the extending direction of the terminal connecting portion 33). A flat surface is formed on a rear end part of the first bent portion 36. A part where this flat surface is formed serves as a pressed portion 38 to be contacted from behind by a jig 37. As shown in FIG. 8, by bringing the jig 37 into contact with this pressed portion 38 and pressing the terminal 21 forward by the jig 37, the terminal 21 is press-fit into the through hole 30 of the housing 18 from behind. Note that a case where the leftmost terminal 21 is pressed by the jig 37 is illustrated for the jig 37.

A right end part of the first bent portion 36 serves as a second bent portion 40 bent downward (an example of an extending direction of an extending portion 39) and connected to the end part 39 to be described later. A flat surface is formed on a front end part of the second bent portion 40. A part where this flat surface is formed serves as a front stop portion 41 for suppressing an excessive forward movement of the terminal 21 when the terminal 21 is press-fit into the through hole 30 of the housing 18. The front stop portion 41 comes into contact with the inner wall surface of the terminal fixing wall 28 from behind, whereby the terminal 21 is suppressed from being excessively press-fit.

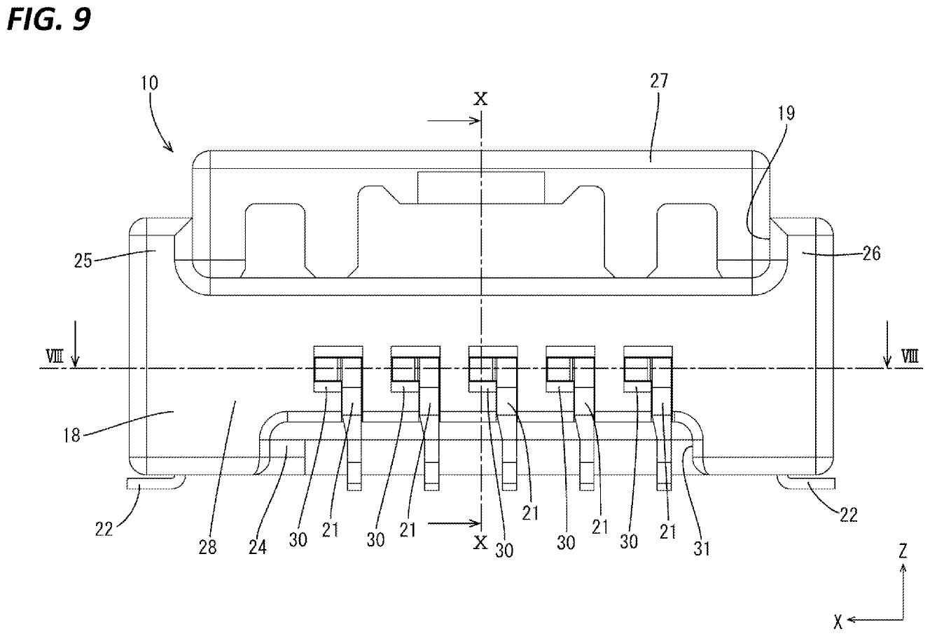

As shown in FIG. 6, a part extending downward from the second bent portion 40 toward the bottom wall 24 serves as the extending portion 39. The extending portion 39 extends along the outer surface of the terminal fixing wall 28. As shown in FIG. 9, an upper end part of the extending portion 39 is formed wider than a lower end part of the extending portion 39 in the lateral direction.

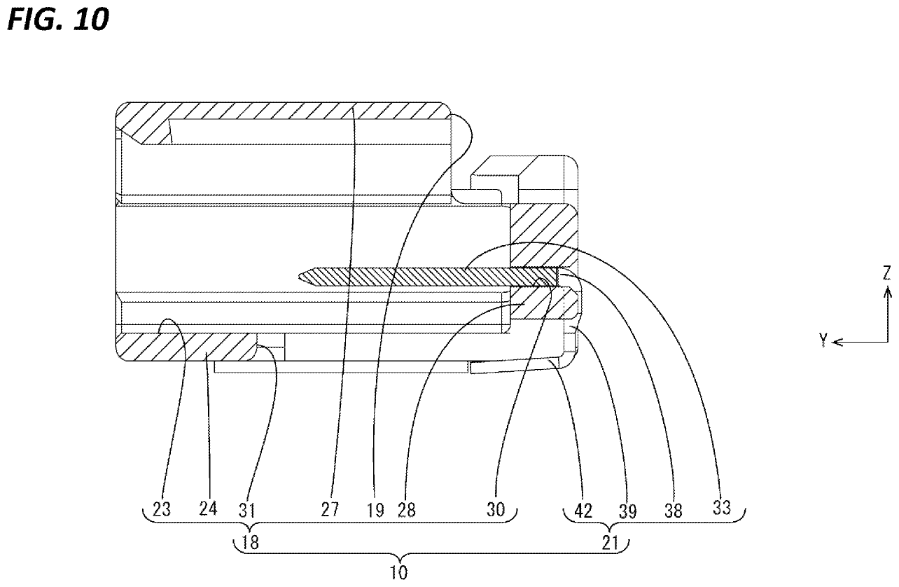

As shown in FIG. 10, the lower end part of the extending portion 39 is formed with a board connecting portion 42 bent to extend forward. As shown in FIGS. 1 and 2, the board connecting portion 42 is connected to the terminal land 16 formed on the upper surface of the circuit board 13 by soldering. The board connecting portion 42 and the terminal land 16 are fixed by solder 43 solidified after being melted by a known method such as reflow soldering. Note that the solder 43 is schematically shown for the convenience of description in FIGS. 1 and 2. The shape (e.g. fillet shape or the like) of the solder 43 is not limited to the shown one. The terminal land 16 is continuous with the conductive path 14 formed on the upper surface of the circuit board 13.

As shown in FIG. 1, with the terminal 21 fixed to the terminal fixing wall 28, the board connecting portion 42 is located to extend in the front-rear direction in a region between the bottom wall 24 and the circuit board 13.

As shown in FIG. 8, the terminal connecting portion 33 and the board connecting portion 42 are formed at positions shifted in the vertical direction (an example of a direction intersecting the bottom wall 24). Particularly, the board connecting portion 42 is located to the right of the terminal connecting portion 33 when viewed from above.

As shown in FIG. 5, with the terminal 21 fixed to the terminal fixing wall 28, the board connecting portion 42 is disposed at a position corresponding to the upper opening 19 formed in the upper wall 27 of the housing 18 in the vertical direction. Further, with the terminal 21 fixed to the terminal fixing wall 28, the board connecting portion 42 is disposed at a position corresponding to the lower opening 31 formed in the bottom wall 24 of the housing 18 in the vertical direction. In this way, the board connecting portion 42 can be viewed through the upper and lower openings 19, 31 when viewed from above.

[Fixing Members 22]

As shown in FIG. 5, the fixing members 22 for fixing the housing 18 on the circuit board 13 by soldering are mounted on both left and right side surfaces of the housing 18. The fixing member 22 is formed by press-working a metal plate. Mounting ribs 44 to be fit into the locking grooves 32 formed in the housing 18 are formed on side edges of the fixing member 22. As shown in FIG. 2, a lower end part of the fixing member 22 is soldered to the fixing land 15 provided on the circuit board 13 by solder 45.

[Manufacturing Process of Board Connector 10 and Electrical Device 11]

Next, an example of a manufacturing process of the board connector 10 and the electrical device 11 according to the embodiment is described. Note that the manufacturing process of the board connector 10 and the electrical device 11 is not limited to that described below.

As shown in FIG. 6, the terminals 21 are formed by press-working the metal plate material into a predetermined shape. The housing 18 is formed by injection-molding a synthetic resin material.

As shown in FIG. 8, the terminal connecting portion 33 of the terminal 21 is press-fit into the through hole 30 of the housing 18 from behind. By bringing the jig 37 into contact with the pressed portion 38 of the terminal 21 from behind, the terminal 21 is pressed forward by the jig 37. The front and rear projections 34, 35 of the terminal 21 bite into the inner wall of the through hole 30, whereby the terminal 21 is fixed to the terminal fixing wall 28.

On the other hand, the solder 43 is applied in advance to the terminal lands 16 and the fixing lands 15 where soldering on the surface of the circuit board 13 is planned. Thereafter, the board connector 10 is placed at a predetermined position on the surface of the circuit board 13. At this time, the board connecting portions 42 of the terminals 21 are placed on the terminal lands 16 and the lower end edges of the fixing members 22 are placed on the fixing lands 15.

In this state, the circuit board 13 having the board connector 10 placed thereon is passed through the inside of a reflow furnace (not shown), whereby the solder 43 applied to the circuit board 13 in advance is melted and adheres to the board connecting portions 42 of the terminals 21. Further, the melted solder 45 adheres to the lower end edges of the fixing members 22. If the solder 43 and the solder 45 are cooled and solidified, the terminal connecting portions 42 of the terminals 21 are fixed on the terminal lands 16 and conductively connected, the fixing members 22 are fixed to the fixing lands 15 and the entire board connector 10 is fixed to the circuit board 13 (see FIG. 2).

The case 12 is formed by injection-molding a synthetic resin. The circuit board 13 mounted with the board connector 10 is accommodated into the case 12 and fixed to the case 12. With the circuit board 13 fixed to the case 12, the cover portion 20 of the case 12 covers the upper opening 19 of the housing 18 from above. In this way, the electrical device 11 is completed (see FIG. 1).

[Functions and Effects of Embodiment]

Next, functions and effects of the embodiment are described. The board connector 10 according to the embodiment is to be mounted on the circuit board 13 including the conductive paths 14, and provided with the housing 18 and the terminals 21 to be fixed to the housing 18. The housing 18 includes the terminal fixing wall 28, through which the terminals 21 are passed to be fixed, the bottom wall 24 to be placed on the circuit board 13, and the upper wall 27 facing the bottom wall 24. The terminal 21 includes the terminal connecting portion 33 located inside the housing 18 with the terminal 21 fixed to the terminal fixing wall 28, the extending portion 39 disposed from the terminal fixing wall 28 to the outside of the housing 18 and extending toward the bottom wall 24 along the terminal fixing wall 28, and the board connecting portion 42 extending in the region between the bottom wall 24 of the housing 18 and the circuit board 13 on the tip of the extending portion 39 and to be soldered to the conductive path 14 of the circuit board 13. The upper wall 27 includes the upper opening 19 open in at least a part of a region corresponding to the board connecting portions 42 in the direction intersecting the bottom wall 24. The bottom wall 24 includes the lower opening 31 open in at least a part of a region corresponding to the board connecting portions 42 in the direction intersecting the bottom wall 24. The terminal connecting portion 33 and the board connecting portion 42 are formed at the positions shifted in the direction intersecting the bottom wall 24.

A part where the board connecting portions 42 and circuit board 13 are soldered can be easily inspected through the upper opening 19 and the lower opening 31 by viewing or inspection by a camera or the like through the upper opening 19.

Further, according to the embodiment, the first bent portion 36 bent in the direction intersecting the extending direction of the terminal connecting portion 33 on the end part of the terminal connecting portion 33 and the second bent portion 40 bent and connected to the extending portion 39 at the end part of the first bent portion 36 are provided between the terminal connecting portion 33 and the extending portion 39, and a part of the first bent portion 36 opposite to the terminal connecting portion 33 serves as the pressed portion 38, with which the jig 37 for press-fitting the terminal 21 into the housing 18 is brought into contact.

In the part of the first bent portion 36 opposite to the terminal connecting portion 33, a region corresponding to at least a cross-sectional area of the terminal connecting portion 33 can be pressed by the jig 37. In this way, a step of press-fitting the terminal 21 into the housing 18 can be reliably performed.

Further, according to the embodiment, a part of the second bent portion 40 opposite to the extending portion 39 serves as the front stop portion 41 for suppressing the terminal 21 from being excessively press-fit into the housing 18.

By the contact of the front stop portion 41 with the terminal fixing wall 28, the terminal 21 is suppressed from being excessively press-fit.

Further, the electrical device 11 according to the embodiment is provided with the board connector 10, the circuit board 13 mounted with the board connector 10 and the case 12 for accommodating the circuit board 13 mounted with the board connector 10, and the case 12 includes the cover portion 20 projecting toward the housing 18 and configured to cover the upper opening 19 at the position corresponding to the upper opening 19 of the board connector 10.

By covering the upper opening 19 with the cover portion 20, the entrance of external matters such as dust into the housing 18 can be suppressed. In this way, the electrical connection reliability of the board connector 10 can be improved.

### OTHER EMBODIMENTS

(1) The lower opening 31 may be omitted.

(2) The case 12 may not include the cover portion 20.

(3) The upper opening 19 may be covered by assembling a cover member separate from the housing 18.

(4) The terminals 21 may be mounted in two or more rows in the housing 18.

(5) One, two to four, or six or more terminals 21 may be provided.

### LIST OF REFERENCE NUMERALS

10: board connector
11: electrical device
12: case
13: circuit board
14: conductive path
15: fixing land
16: terminal land
17: connector opening
18: housing
19: upper opening
20: cover portion
21: terminal
22: fixing member
23: opening
24: bottom wall
25: left side wall
26: right side wall
27: upper wall
28: terminal fixing wall
29: bulging portion
30: through hole
31: lower opening
32: locking groove
33: terminal connecting portion
34: front projection
35: rear projection
36: first bent portion
37: jig
38: pressed portion
39: extending portion
40: second bent portion
41: front stop portion
42: board connecting portion
43, 45: solder
44: mounting rib

1. A board connector to be mounted on a circuit board including a conductive path, comprising:
a housing; and
a terminal to be fixed to the housing,
the housing including a terminal fixing wall, the terminal being passed through and fixed to the terminal fixing wall, a bottom wall to be placed on the circuit board and an upper wall facing the bottom wall,
the terminal including a terminal connecting portion located inside the housing with the terminal fixed to the terminal fixing wall, an extending portion disposed from the terminal fixing wall to outside of the housing and extending toward the bottom wall along the terminal fixing wall and a board connecting portion extending in a region between the bottom wall of the housing and the circuit board on a tip of the extending portion and to be soldered to the conductive path of the circuit board,
the upper wall including an upper opening open in at least a part of a region corresponding to the board connecting portion in a direction intersecting the bottom wall,
the terminal connecting portion and the board connecting portion being formed at positions shifted in the direction intersecting the bottom wall,
the board connecting portion being bent forward to extend from an end part of the extending portion at the bottom wall side if a direction from the terminal fixing wall to inside of the housing is defined as a forward direction,
the bottom wall of the housing including a lower opening open in a region corresponding to the board connecting portion, and
a front end of the board connecting portion being located forward of a front surface of the terminal fitting wall, the board connecting portion being visible through the upper opening and the lower opening when viewed from above.

2. The board connector of claim 1, wherein:
a first bent portion bent in a direction intersecting an extending direction of the terminal connecting portion on an end part of the terminal connecting portion and a second bent portion bent and connected to the extending portion on an end part of the first bent portion are provided between the terminal connecting portion and the extending portion, and
a part of the first bent portion opposite to the terminal connecting portion serves as a pressed portion, a jig for press-fitting the terminal into the housing being brought into contact with the pressed portion.

3. The board connector of claim 2, wherein a part of the second bent portion opposite to the extending portion serves as a front stop portion for suppressing the terminal from being excessively press-fit into the housing.

4. (canceled)

5. An electrical device, comprising:
the board connector of claim 1;
a circuit board mounted with the board connector; and
a case for accommodating the circuit board mounted with the board connector,
the case including a cover portion at a position corresponding to the upper opening of the board connector, the cover portion projecting toward the housing and covering the upper opening.
